(19) United States
(12) Patent Application Publication
(10) Pub. No.: US 2008/0128911 A1
(43) Pub. Date: Jun. 5, 2008

(54) Semiconductor package and method for manufacturing the same

(75) Inventor: Toshinori Koyama, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/984,070

(22) Filed: Nov. 13, 2007

(30) Foreign Application Priority Data
Nov. 15, 2006 (JP) P.2006-309452

(51) Int. Cl. H01L 23/52; H01L 21/4763

(52) U.S. Cl. 257/759; 438/623; 257/E23.141; 257/E21.495

(57) ABSTRACT

A semiconductor package includes: a build-up wiring structure in which an insulating layer formed from a resin and a wiring layer formed from a conductive plating layer are stacked one on top of the other; a fine-wiring structure which is formed by patterning a conductive foil on a resin tape to which the conductive foil is attached, and includes a wiring layer that is finer than the wiring layer of the build-up wiring structure; and a junction layer which is formed from a thermoplastic resin and interposed between the build-up wiring structure and the fine-wiring structure, thereby bonding the structures together.

This application is based on and claims priority from Japanese Patent Application No. 2006-309452, filed on Nov. 15, 2006, the entire contents of which are hereby incorporated by reference.

### BACKGROUND OF THE INVENTION

1. Technical Field

The present disclosure relates to a semiconductor package having a fine-wiring structure as well as to a method for manufacturing the same.

2. Background Art

Nowadays, many semiconductor packages employ a multilayer wiring structure realized by a build-up technique, and fine-wiring has been implemented to a line width of about 15 to 20 μm by means of a semi-additive method.

However, further miniaturization to a line width of 10 μm or less cannot be realized because of the following problems (1) to (4) in the related-art techniques.

(1) Planarity and Smoothness of Wire Formation Surface

In order to realize fine-wiring, high flatness of a lower layer is required. However, according to the build-up technique, irregularities formed under the influence of a lower pattern are not negligible. Further, smoothing a resin layer serving as a base material is advantageous. However, in order to ensure a mechanical anchoring effect for the sake of acquiring adhesion between the resin layer and a wiring layer, the surface of the resin layer must be roughened.

(2) Resolution of Plating Resist

Although miniaturization of wiring depends on the resolution of a plating resist, the resist requires a thickness which is greater than the thickness of plating under the semi-additive method. Hence, a high aspect ratio; for example, a ratio of a plating width of 10 μm to a resist thickness of 20 to 25 μm, is achieved, and hence there is a limit on attainable resolution.

(3) Uniform Thickness of Wiring

Since wirings are formed by means of plating, there is a limit on the uniform thickness of wirings, and a limit also exists in impedance matching.

(4) Undercut Arising during Etching of a Seed Layer

An undercut is likely to arise when a seed layer is etched after wire plating, and there is a limit on miniaturization.

Japanese Patent Unexamined Documents: JP-A-2001-339167 and JP-A-2005-45150 disclose that a multilayer wiring structure is formed by means of a build-up technique which performs heating and contact bonding by using prepreg sheet (a sheet which is generally formed by impregnating glass cloth with resin). However, measures against the problems (1) to (4) are not disclosed.

### SUMMARY OF THE INVENTION

Exemplary embodiments provide a semiconductor package in which wiring is miniaturized beyond a related-art limit and a method for manufacturing the semiconductor package.

In order to achieve the objective, a semiconductor package comprises:

a build-up wiring structure in which an insulating layer formed from a resin and a wiring layer formed from a conductive plating layer are stacked one on top of the other;

a fine-wiring structure which is formed by patterning a conductive foil on a resin tape to which the conductive foil is attached, and includes a wiring layer that is finer than the wiring layer of the build-up wiring structure; and

a junction layer which is formed from a thermoplastic resin and interposed between the build-up wiring structure and the fine-wiring structure, thereby bonding the structures together.

According to another aspect of the present invention, the resin tape may be formed from a polyimide film, and the conductive foil is formed from a copper.

According to another aspect of the present invention, the roughness of the surface of the conductive foil may be Ra=0.1 or less.

According to another aspect of the present invention, a width of the wiring layer of the fine-wiring structure on an upper side may be 10 μm or less.

According to another aspect of the present invention, the junction layer may be formed from a thermoplastic polyimide resin.

According to another aspect of the present invention, a method for manufacturing a semiconductor package comprises:

a) stacking an insulating layer formed from a resin and a wiring layer formed from a conductive plating layer one on top of the other, thereby forming a build-up wiring structure;

b) forming a thermoplastic resin layer on the build-up wiring structure;

c) forming a wiring layer that is finer than the wiring layer of the build-up wiring structure by means of patterning a conductive foil on a resin tape to which the conductive foil is attached, thereby forming a fine-wiring structure; and

d) plasticizing the thermoplastic resin layer by means of heating and pressurizing the fine-wiring structure superimposed on the thermoplastic resin layer of the build-up wiring structure, thereby bonding the structures together.

According to another aspect of the present invention, in the c) step, the fine-wiring structure may be fabricated on the resin tape on the reel-to-reel line.

In the aspect of the present invention, the build-up wiring structure and the fine-wiring structure are separately fabricated, and these structures are bonded to each other, to thus manufacture a semiconductor package. Accordingly, only an upper portion of the semiconductor package where a semiconductor element is to be mounted is formed into a fine-wiring structure, and a lower portion of the semiconductor package can be formed as a build-up wiring structure. The build-up wiring structure can be formed according to an unspecified, appropriate method, such as a semi-additive method, as in the related art. In the meantime, in connection with the fine-wiring structure, a wiring layer which is finer than a wiring layer of the build-up wiring structure can be formed by means of patterning a conductive foil on a resin tape; namely, by means of a subtractive method. In this fine-wiring structure, fine wiring is formed in conformity with a semiconductor element to be mounted in the semiconductor package.

### BRIEF DESCRIPTION OF THE DRAWINGS

FIG. 1 is a cross-sectional view showing the structure of a semiconductor package according to a preferred embodiment of the present invention;

FIGS. 2A to 2C are cross-sectional views showing processes for manufacturing an assembly of a build-up wiring structure and a junction layer of the semiconductor package shown in FIG. 1 according to the preferred embodiment of the present invention; and

FIGS. 3A to 3E are cross-sectional views showing processes for manufacturing a fine-wiring structure of the semiconductor package shown in FIG. 1 according to the preferred embodiment of the present invention.

### DETAILED DESCRIPTION OF EXEMPLARY EMBODIMENTS

According to the present invention, a fine-wiring structure is formed by means of a subtraction method, whereby the drawbacks of the related art are resolved as follows.

(1) Flatness and Smoothness of Wire Formation Surface

Upon formation of a fine-wiring structure, a wiring layer connected to a semiconductor element can be formed by means of patterning a conductive foil of a resin tape (conductive clad resin tape) to which the conductive foil is attached; namely, by means of a subtractive method. Hence, the flatness and smoothness of the wire formation surface are originally ensured.

(2) Resolution of Plating Resist

In connection with (1), the fine-wiring structure is formed by means of patterning the conductive foil under the subtractive method. Accordingly, an etching resist used for patterning may be thinly formed to about several micrometers, and thus high resolution can be acquired readily.

(3) Uniform Thickness of Wiring

In a fine-wiring structure on which a semiconductor element is mounted, wiring is formed by means of patterning a conductive foil. Hence, a uniform thickness of wiring is ensured in correspondence with the thickness of the conductive foil.

(4) Undercut Arising Upon Etching of Seed Layer

In a fine-wiring structure on which a semiconductor element is mounted, wiring is formed by means of patterning a conductive foil. Hence, a seed layer necessary for the semi-additive method is not required. Consequently, etching is not performed, and an undercut incident to etching does not arise.

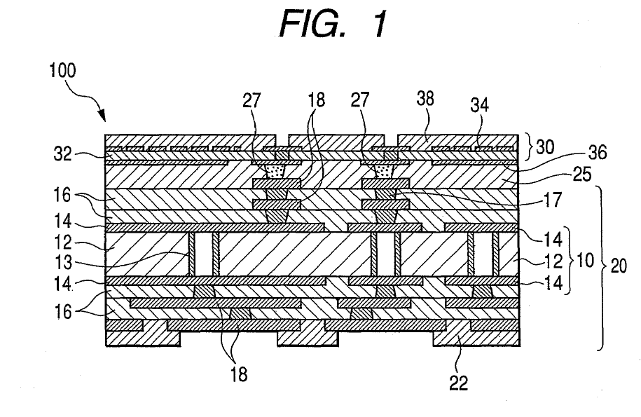

An example of semiconductor package according to a preferred embodiment of the present invention will be described by reference to FIG. 1.

A semiconductor package 100 includes a lower build-up wiring structure 20 and an upper fine-wiring structure 30 being bonded together by a junction layer 25 sandwiched therebetween.

The build-up wiring structure 20 is formed by stacking an insulation layer 16 formed from a resin and a wiring layer 18 formed from a conductor, one on top of the other, on both surface of a core substrate 10 having a base wiring layer 14. The base wiring layer 14 is formed by patterning a conductive foil formed on both surface of an insulation base material 12 such as a resin, through etching. The base wiring layers 14 formed on both surfaces of the core substrate 10 are connected together at required points by means of through holes 13 penetrating through the insulating substrate 12. The base wiring layer 14 and the wiring layer 18 that is the first layer of the multilayer structure and the wiring layers 18 of adjacent levels of the multilayer structure are connected together at required points by means of vias 17 penetrating through the insulating layer 16.

A wiring layer 34 on an upper surface side of the fine-wiring structure 30 is used for (an interposer) connection with electrode terminals of a semiconductor element mounted on a semiconductor package. The wiring layer 34 is formed by the subtractive method under which patterning is performed by etching a conductive foil on a resin tape 32 to which the conductive foil is attached; and is a wiring layer that is finer than wiring layers 14 and 18 of a build-up wiring structure 20. Specifically, the wiring layers 14 and 18 of the build-up wiring structure 20 are formed to wiring width of at minimum about 15 to 20 μm. The upper wiring layer 34 of the fine-wiring structure 30 is formed to a wiring width of 10 μm or less under the subtractive method.

According to the resin tape 32 to which the conductive foil is attached, and which is employed in the fine-wiring structure 30, single-sided copper clad polyimide film is typically employed. Namely, a polyimide film is used as the resin tape and a copper is used as the conductive foil, and the copper is attached onto single-surface of the polyimide film. In the tape, for instance, a copper foil having a thickness of 9 μm is attached to one surface of a polyimide film having a thickness of 20 to 25 μm. The flatness and smoothness of the surface of this copper foil are extremely high, and the roughness of the surface is Ra=0.1 or less. Therefore, the fine-wiring layer 34 formed under the subtractive method—by which the copper foil is patterned by means of etching—has high flatness and smoothness derived from the copper foil and is firmly bonded to the resin tape 32 serving as a base material by means of an adhesive, and roughening of the resin tape 32 is not required. Conventionally, the surface of a base material is roughened to Ra=0.6 to 0.7 μm for ensuring adhesion between wiring layers. A lower layer of the wiring layer inevitably becomes roughened correspondingly.

A wiring layer 36 on the lower surface of the fine-wiring structure 30 is used for connection with the lower build-up wiring structure 20. As will be described in detail later, the wiring layer 36 is formed by means of filling, plating, and patterning vias. In particular, there is no necessity for miniaturizing the wiring layer for the sake of connection with a semiconductor element.

The junction layer 25—which is interposed between the build-up wiring structure 20 and the fine-wiring structure 30 and which bonds the structures together—is formed from a thermoplastic resin. From the viewpoint of strength and insulating property, a thermoplastic polyimide resin is preferred as a material for the junction layer 25. Liquid-crystal polymer may also be used in place of a polyimide resin. The liquid-crystal polymer is more advantageous than a polyimide resin in terms of low thermal expansion, low cost, a non-hydrophilic property, and low gas permeability or the like, and is often used as a polyimide substitute for a flexible substrate. The fine-wiring structure 30 and the build-up wiring structure 20 are connected together at required points by means of the vias 27 penetrating through the junction layer 25.

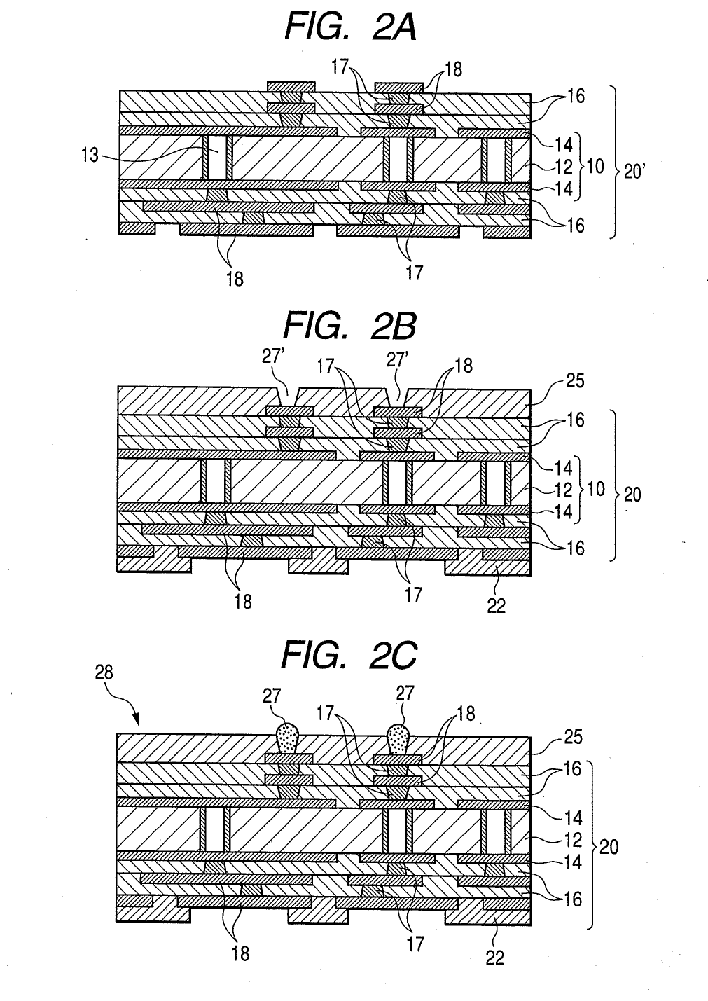

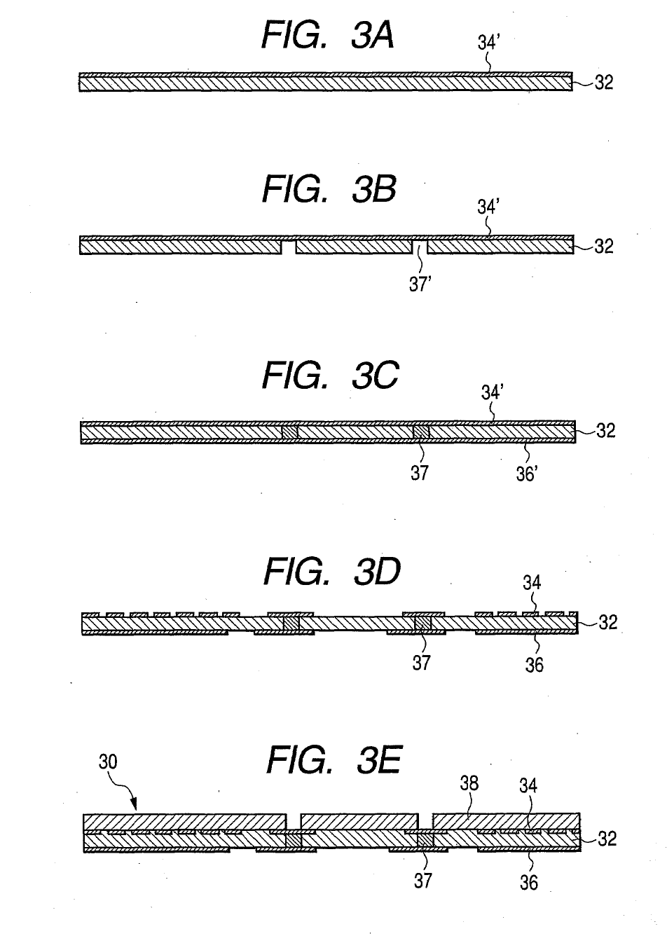

A method for manufacturing a semiconductor package shown in FIG. 1 will now be described by reference to FIGS. 2A to 3E.

A method for manufacturing the build-up wiring structure 20 shown in FIG. 1 will first be described by reference to FIGS. 2A to 2C.

A build-up wiring substrate 20′ shown in FIG. 2A is formed. Specifically, a double-sided copper clad laminated board—where a copper foil is attached onto both surfaces of the insulting base material 12 such as an epoxy resin—is used as the core substrate 10. The conductive foil is patterned by means of etching, to thus form the base wiring layer 14. The through holes 13 for interconnecting the base wiring layers 14 on both surfaces are also formed at required points.

The insulating layer 16 formed from lamination of a thermosetting resin sheet such as an epoxy resin; via holes opened in the insulating layer 16 by means of laser beam machining or the like; a conductive layer and vias 17 which are formed by means of copper seed plating and copper electrical plating; and the wiring layer 18 formed by means of patterning the conductive layer using chemical etching or the like are sequentially provided on the base wiring layers 14 on both surfaces. Subsequently, both surfaces of the core substrate 10 are subjected to analogous operations in accordance with the number of required wiring layers, to thus repeat formation of layers of a multilayer structure. Thus, an illustrated build-up wiring board 20′ is acquired.

As shown in FIG. 2B, a junction layer 25 formed from a thermoplastic resin is formed on the upper surface of the build-up wiring substrate 20′. Specifically, a thermoplastic resin sheet, such a polyimide resin, is stacked, and via holes 27′ are formed by means of laser beam machining, or the like.

As illustrated, a solder resist layer 22 is formed on a lower surface of the build-up wiring substrate 20′, so that the build-up wiring structure 20 is completed.

Exposed portions of the upper and lower wiring layers 18 are plated with nickel/gold, to thus protect the wiring layer from contamination or oxidation.

As shown in FIG. 2C, the via holes 27′ formed in the upper surface of the junction layer 25 are subjected to solder plating or filled with a conductive resin, to thus form bumps 27.

Through foregoing processing, an assembly 28—which is formed from the build-up wiring structure 20 and the junction layer 25 provided thereon—is obtained.

Aside from foregoing processing, the fine-wiring structure 30 is formed as shown in FIGS. 3A to 3E.

As shown in FIG. 3A, a single-sided copper clad polyimide film 32 whose upper surface is covered with a copper foil 34′ is used as the resin tape to which the conductive foil is attached. By way of typical example, the polyimide film 32 serving as a base material has a thickness of about 20 to 25 μm, and a copper foil 34′ attached to the tape has a thickness of 9 μm. As will be described later, the copper foil 34′ is used for forming the fine-wiring layer 34 by means of patterning under the subtractive method.

As shown in FIG. 3B, via holes 37′ are opened in a lower surface of the film 32 by means of laser beam machining, and the like. The via holes 37′ penetrate through the film 32 from the lower surface thereof and are closed by the copper foil 34′ provided on an upper surface of the film 32.

As shown in FIG. 3C, a lower conductor layer 36′ and vias 37 are formed by means of copper seed plating and copper electrical plating from the lower surface side of the film.

As shown in FIG. 3D, both surfaces are patterned by means of chemical etching, or the like, thereby simultaneously forming the upper wiring layer 34 and the lower wiring layer 36.

As mentioned above, the wiring layer 34 on the upper surface is used for connection (an interposer) with electrode terminals of a semiconductor element which is to be mounted on a completed semiconductor package. The wiring layer 34 is formed by means of the subtractive method under which patterning is performed by etching a copper foil on attached to the film 32. Hence, the wiring layer 34 can be miniaturized more readily than are the wiring layers 14 and 18 of the build-up wiring structure 20 formed by means of the semi-additive method.

Specifically, under the semi-additive method, an etching resist—which is greater in thickness than the wiring layer as an object of etching—is required. For this reason, since an etched portion resultantly has a high aspect ratio, the build-up wiring structure made by the semi-additive method is not suitable for fine-wiring that requires high resolution. In contrast, a thin resist etching resist is sufficient for the subtractive method. Hence, high resolution is readily achieved, and fine-wiring can be patterned reliably.

As mentioned previously, a typical limit of the minimum line width of the wiring layers 14 and 18 of the build-up wiring structure 20 formed under the semi-additive method is about 15 to 20 μm. In the case of the upper wiring layer 34 of the fine-wiring structure 30 formed by use of the subtractive method, a line can be sufficiently formed to a width of 10 μm or less. As mentioned previously, the flatness and smoothness of the surface of the copper foil 34′ are extremely high, and roughness of Ra=0.1 or less is achieved. Consequently, the fine-wiring layer 34 formed under the subtractive method in which a copper foil is patterned through etching exhibits high flatness and smoothness derived from the flatness and smoothness of the copper foil. Further, the fine-wiring layer 34 is firmly bonded to the resin tape 32 that serves as a base material, by means of an adhesive.

Conventionally, the surface of the resin serving as a base material is roughened to Ra=0.6 to 0.7 μm in order to ensure adhesion of a plating wiring layer. A lower layer of a wiring layer formed on the plating wiring layer through plating inevitably reflects the same roughness as that of the base material. Therefore, the thickness of the wiring layer becomes nonuniform, and thus there arises a problem on impedance matching.

According to the present invention, the flatness and smoothness of the wiring layer directly reflect the flatness and smoothness of the copper foil. Hence, the drawbacks in the related art are resolved.

The wiring layer 36 on the lower surface side of the fine-wiring structure 30 is used for connection with the lower build-up wiring structure 20. In contrast with the wiring layer 34 provided on the upper layer of the fine-wiring structure, the wiring layer 36 does not need to be miniaturized for connection with a semiconductor element. Accordingly, the essential requirement is to form the wiring layer 36 by means of copper plating and copper etching; namely, under the semi-additive method.

Finally, as shown in FIG. 3E, a solder resist 38 is formed on the upper surface where the fine-wiring layer 34 is formed, so that the fine-wiring structure 30 is completed. When necessary, the fine-wiring structure may also be coated with an organic film (OSP) for use in preventing oxidation.

Since the fine-wiring structure 30 can be fabricated on the conductive tape 32 on a reel-to-reel line, processing for manufacturing the fine-wiring structure is confined to a comparatively-small tape width of the order of 40 to 100 mm. Hence, there is also an advantage that the thickness of a plating layer is especially made readily uniform. There is further an advantage that variations in etching are made small.

The fine-wiring structure 30 manufactured through the processes shown in FIGS. 3A to 3E is placed on the assembly 28 which is formed from the build-up wiring structure 20 and the junction layer 25 through the processes shown in FIG. 2, and they are bonded together by means of heating and pressurization performed in a vacuum heat pressing system. When the bumps 27 are formed from solder, a heating temperature achieved at that time corresponds to a temperature which enables reflow of the solder bumps 27 and plasticization (fluidization) of the thermoplastic resin 25. The heating temperature is usually set in accordance with a reflow temperature which is higher than the plasticization temperature of a thermoplastic resin. When a Pb-free solder, such as Sn alone or Sn—Ag (—Cu) alloy, is used, the assembly must be heated at a temperature of 250 to 300 degree which are higher than the fusing point of the Pb-free solder. When the bumps 27 are formed from a conductive resin rather than from solder, the heating temperature is set in accordance with the plasticization temperature of the conductive resin or the plasticization temperature of a resin of the junction layer, whichever temperature is higher.

In a typical manufacturing embodiment, the assembly 28 consisting of the build-up wiring structure 20 and the junction layer 25 is formed on a large-sized multi-assembly substrate. As mentioned previously, the fine-wiring structure 30 is fabricated on the conductive tape 32 on the reel-to-reel line. Therefore, the assembly 28 and the fine-wiring structure 30 can be bonded together after the large-sized substrate has been separated into pieces and after the respective assemblies 28 have been placed on the respective fine-wiring structures 30. Alternatively, the assembly 28 and the fine-wiring structure 30 can also be bonded together after the tape 32 has been separated into pieces and after the fine-wiring structures 30 have been placed on the respective assemblies 28 on the large-sized substrate. In the latter case, bonding may also be performed after the large-sized substrate has been cut into middle-sized multi-assembly substrates.

In the present embodiment, the build-up wiring structure 20 is fabricated by use of the core substrate 10. However, the build-up wiring structure is not limited particularly to the core substrate. A core-less structure may also be adopted.

According to the present invention, there are provided a semiconductor package in which wiring is miniaturized beyond a related-art limit and a method for manufacturing the semiconductor package.

While there has been described in connection with the exemplary embodiments of the present invention, it will be obvious to those skilled in the art that various changes and modification may be made therein without departing from the present invention. It is aimed, therefore, to cover in the appended claim all such changes and modifications as fall within the true spirit and scope of the present invention.

What is claimed is:

1. A semiconductor package comprising:
a build-up wiring structure in which an insulating layer formed from a resin and a wiring layer formed from a conductive plating layer are stacked one on top of the other;
a fine-wiring structure which is formed by patterning a conductive foil on a resin tape to which the conductive foil is attached, and includes a wiring layer that is finer than the wiring layer of the build-up wiring structure; and
a junction layer which is formed from a thermoplastic resin and interposed between the build-up wiring structure and the fine-wiring structure, thereby bonding the structures together.

2. The semiconductor package according to claim 1, wherein the resin tape is formed from a polyimide film, and the conductive foil is formed from a copper.

3. The semiconductor package according to claim 2, wherein the roughness of the surface of the conductive foil is Ra=0.1 or less.

4. The semiconductor package according to claim 1, wherein a width of the wiring layer of the fine-wiring structure on an upper side is 10 μm or less.

5. The semiconductor package according to claim 1, wherein the junction layer is formed from a thermoplastic polyimide resin.

6. A method for manufacturing a semiconductor package, comprising:
a) stacking an insulating layer formed from a resin and a wiring layer formed from a conductive plating layer one on top of the other, thereby forming a build-up wiring structure;
b) forming a thermoplastic resin layer on the build-up wiring structure;
c) forming a wiring layer that is finer than the wiring layer of the build-up wiring structure by means of patterning a conductive foil on a resin tape to which the conductive foil is attached, thereby forming a fine-wiring structure; and
d) plasticizing the thermoplastic resin layer by means of heating and pressurizing the fine-wiring structure superimposed on the thermoplastic resin layer of the build-up wiring structure, thereby bonding the structures together.

7. The method for manufacturing a semiconductor package according to claim 6, wherein
in the c) step, the fine-wiring structure is fabricated on the resin tape on the reel-to-reel line.
